(19) United States
(12) Patent Application Publication
(10) Pub. No.: US 2006/0126384 A1
(43) Pub. Date: Jun. 15, 2006

(54) Flash memory integrated circuit with multi-selected modes

(75) Inventors: Gordon Yu, Taipei (TW); Hung-Tse Ho, Taipei City (TW); Chien-Wei Teng, Miaoli City (TW); Ming-Che Chang, Tainan City (TW)

Correspondence Address: BACON & THOMAS, PLLC, 625 SLATERS LANE, FOURTH FLOOR, ALEXANDRIA, VA, 22314, US

(73) Assignee: C-One Technology Corporation, Hsin-Chu City (TW)

(21) Appl. No.: 11/218,443

(22) Filed: Sep. 6, 2005

(30) Foreign Application Priority Data
Dec. 9, 2004 (TW) 093138108

(51) Int. Cl. G11C 5/02; G11C 11/34

(52) U.S. Cl. 365/185.05; 365/51

(57) ABSTRACT

The present invention provides a flash memory integrated circuit with multi-selected modes. The flash memory integrated circuit comprises a base, a plurality of flash memory dies, and a transformation device. The plurality of flash memory dies and the transformation device are disposed on the base. And the multi-selected modes can be switched by inputting control signals to the transformation device for controlling the flash memory dies to perform such a transformation procedure.

### BACKGROUND OF THE INVENTION

1. Field of the Invention

The present invention relates to an integrated circuit (IC) with a multi-selected modes, and more particularly, to a flash memory integrated circuit with a multi-selected modes which is selected from an 8-bit mode, a 16-bit mode, a 32-bit mode, and so on.

2. Description of Related Art

Comparing with general memories, the flash memory can maintain stored data without power supply such that the written data can still be stored in the memory after turning off the power. Further, with the characteristics of small volume and large capacity, the flash memory is widely applied in various portable 3C (communication, computer, and consumer electronics) products, including personal digital assistants (PDA), wireless mobile communication devices such as mobile phones and personal handy-phone systems (PHS), and digital memory cards (like compact flash (CF) cards, multimedia cards (MMC), and smart media (SM) cards) compatible with digital cameras, movable drives, and switch cards. Usually, the flash memory is adapted for the 8-bit mode. However, with the improvement of technology, not only 8-bit mode, but also 16-bit mode, 32-bit mode, and even 64-bit mode are gradually developed. Since the memory mode of general flash memory integrated circuits cannot be modified after being packaged, it brings about many usage limitations for users. And the inventory problem may come to the manufacturers because the usage of the same flash memory die cannot be transformed after being packaged.

Therefore, it is desirable to provide an improved flash memory integrated circuit with multi-selected modes to mitigate and/or obviate the aforementioned problems.

### SUMMARY OF THE INVENTION

The flash memory integrated circuit with multi-selected modes of the present invention comprises a base, a plurality of flash memory dies, and a transformation device. The plurality of flash memory dies and the transformation device are disposed on the base, and the aforementioned transformation device has at least one input and a plurality control lines each corresponding connected to each flash memory die. The above input receives an input control signal for switching to a plurality of memory modes of the flash memory dies according to the control lines, such that the user adjusts the flash memory integrated circuit with multi-selected modes to a required memory mode, such as an 8-bit mode, a 16-bit mode, a 32-bit mode, and so on.

The plurality of flash memory dies and the transformation device can also share the same body for packaging.

Further, the flash memory dies are disposed on the base, or independently disposed on the base.

Other objects, advantages, and novel features of the invention will become more apparent from the following detailed description when taken in conjunction with the accompanying drawings.

### BRIEF DESCRIPTION OF THE DRAWINGS

FIG. 1 illustrates a schematic drawing of a package structure of a preferred embodiment according to the present invention;

FIG. 2 illustrates a schematic drawing of a circuit structure of the preferred embodiment according to the present invention; and

FIG. 3 illustrates a flash memory integrated circuit with multi-selected modes of the preferred embodiment according to the present invention.

### DETAILED DESCRIPTION OF THE PREFERRED EMBODIMENT

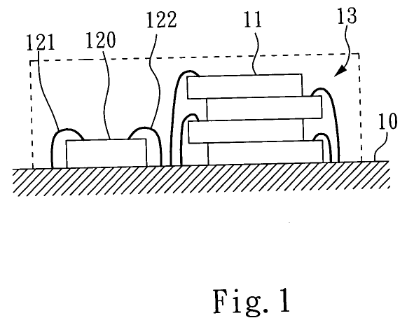

Please refer to FIG. 1. FIG. 1 illustrates a schematic drawing of a package structure of a preferred embodiment according to the present invention. As shown in FIG. 1, there are four flash memory dies 11 each mutually superimposed on a base 10, and packaged within a body 13. A transformation device 120 is also disposed on the base 10, and packaged within the same body 13. In this embodiment, the transformation device 120 has two inputs 121 for receiving input control signals so as to decide the memory mode by decoding the input control signals. The transformation device 120 further comprises four control lines 122 each correspondingly connected to four flash memory dies 11 so as to control each flash memory die 11 to switch to multiple memory modes.

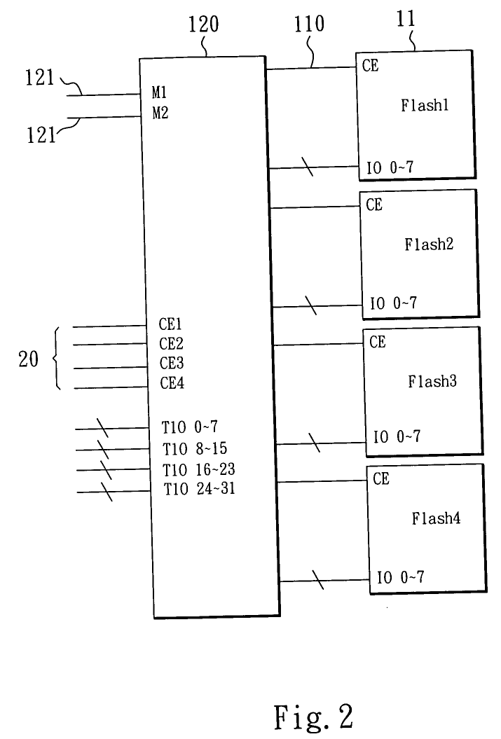

With reference to FIG. 2, it illustrates a schematic drawing of a circuit structure of the preferred embodiment according to the present invention. In FIG. 2, each flash memory die 11 is configured as an 8-bit mode, and has CE pins 110 and a set of input/output (IO) 0-7. Consequently, these four flash memory dies 11 can be combined for being configured as a maximum of a 32-bit mode. The transformation device 120 receives input control signals through the input 121 for switching the flash memory mode. If the input control signals of the input line M1 and the input line M2 are respectively logic ‘0’ and logic ‘0’, the flash memory integrated circuit is configured as an 8-bit (=8>2²) mode; if the input control signals of the input line M1 and the input line M2 are respectively logic ‘0’ and logic ‘1’, the flash memory integrated circuit is configured as a 16-bit (=8×2¹) mode; if both input control signals are logic ‘1’, the flash memory integrated circuit is then configured as a 32-bit (=8×2²) mode. The transformation device 120 further includes a CE pin set 20, wherein each CE pin CE1-CE4 of the CE pin set 20 is correspondingly connected to the CE pin 110 of each flash memory die 11 for respectively driving the CE pin 110. Moreover, there are four external IO's TIO 0-7, TIO 8-15, TIO 16-23 and TIO 24-31 each correspondingly connected to the IO 0-7 of the aforementioned four flash memory dies 11 according to different bit modes. Therefore, users can provide different input control signals based on their requirements or selections for accomplishing switching to different modes.

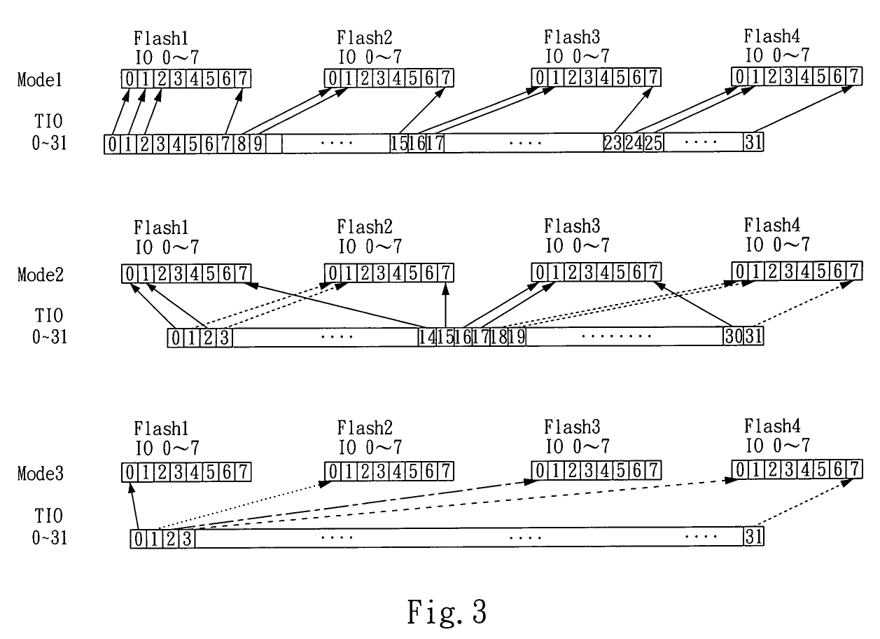

Please refer to FIG. 3. FIG. 3 illustrates a flash memory integrated circuit with multi-selected modes of the preferred embodiment according to the present invention. Those multi-selected modes comprise a first mode (the 8-bit mode), a second mode (the 16-bit mode), and a third mode (the 32-bit mode) for the transformation device 120 to process a corresponding transformation procedure. When the input status is configured as the first mode, the TIO 0-7 of the external TIO 0-31 of the transformation device 120 is correspondingly connected to the IO 0-7 of the first flash memory die 11, the external TIO 8-15 is correspondingly connected to the IO 0-7 of the second flash memory die 11, the external TIO 16-23 is correspondingly connected to the IO 0-7 of the third flash memory die 11, and the external TIO 24-31 is correspondingly connected to the IO 0-7 of the fourth flash memory die 11. Therefore, it can be regarded as four independent 8-bit flash memory dies 11.

If the input status is configured as the second mode (16-bit mode), the first flash memory die 11 and the second flash memory die 11 are regarded as the same memory unit, while the third flash memory die 11 and the fourth flash memory die 11 are regarded as another memory unit. The connection between the transformation device 120 and the two memory units is shown in FIG. 3. TIO 0 is connected to IO 0 of the first flash memory die 11; TIO 1 is connected to IO 0 of the second flash memory die 11; TIO 2 is connected to IO 1 of the first flash memory die 11; TIO 3 is connected to IO 1 of the second flash memory die 11; and son on. Likewise, the connection between TIO 16-31 and the third and fourth flash memory dies 11 is similar to that between TIO 0-15 and the first and second flash memory dies 11. That is, TIO 16 is connected to IO 0 of the third flash memory die 11; TIO 17 is connected to IO 0 of the fourth flash memory die 11, and so forth. Briefly, the connection between the transformation device 120 and two flash memory dies 11 is mutually interlaced under the second mode.

If the input status is configured as the third mode (32-bit mode), the first, second, third and fourth flash memory dies 11 are all configured as a whole memory unit, and the connection between the transformation device 120 and the memory unit is also mutually interlaced. As shown in FIG. 3, while in the 32-bit mode, TIO 0 is connected to IO 0 of the first flash memory die; TIO 1 is connected to IO 0 of the second flash memory die 11; TIO 2 is connected to IO 0 of the third flash memory die 11; TIO 3 is connected to IO 0 of the fourth flash memory die 11, and so on. Consequently, the transformation device 120 is capable of switching the aforesaid three memory modes for complying with user's requirement or selection.

Although the present invention has been explained in relation to its preferred embodiment, it is to be understood that many other possible modifications and variations can be made without departing from the spirit and scope of the invention as hereinafter claimed.

What is claimed is:

1. A flash memory integrated circuit with multi-selected modes, comprising:
a base;
a plurality of flash memory dies coupled to the base; and
a transformation device disposed on the base, comprising a plurality of control lines and at least one input, wherein the input receives an input control signal for switching to a plurality of memory modes so as to control each flash memory die according to the switched memory mode, such that the plurality of control lines are correspondingly connected to the flash memory dies.

2. The flash memory integrated circuit with multi-selected modes as claimed in claim 1, wherein each flash memory die is configured as an N-bit mode.

3. The flash memory integrated circuit with multi-selected modes as claimed in claim 1, wherein there are 2^{M} flash memory dies, and the plurality of memory modes include N×2⁰˜N×2^{M}-bit modes, where M=0 is a predetermined integer.

4. The flash memory integrated circuit with multi-selected modes as claimed in claim 1, further comprising a body for packaging the flash memory dies and the transformation device.

5. The flash memory integrated circuit with multi-selected modes as claimed in claim 1, wherein the flash memory dies are superimposed on the base.

6. The flash memory integrated circuit with multi-selected modes as claimed in claim 3, wherein N=8 and M=2, and four flash memory dies are disposed on the base for being configured as an 8-bit mode, a 16-bit mode and a 32-bit mode.

7. The flash memory integrated circuit with multi-selected modes as claimed in claim 1, wherein the transformation device further comprises a plurality of external input/outputs for receiving and transmitting external information, where each flash memory further has a plurality of data input/outputs for respectively connecting to the transformation device such that the transformation device performs a corresponding transformation procedure between the external input/outputs and the data input/outputs while under each memory mode.
